(19) United States
(12) Patent Application Publication
(10) Pub. No.: US 2024/0069596 A1
(43) Pub. Date: Feb. 29, 2024

(54) Electronic Devices with Sweat Mitigation Structures

(71) Applicant: Apple Inc., Cupertino, CA (US)

(72) Inventors: Adam Y Kollgaard, San Jose, CA (US); Kristine S Atom, Sunnyvale, CA (US); Vedant A Dhandhania, San Jose, CA (US); Ian A Guy, Santa Cruz, CA (US); Dustin A Hatfield, Campbell, CA (US); Shannon Pomeroy, San Francisco, CA (US); Paul X Wang, Cupertino, CA (US)

(21) Appl. No.: 18/350,628

(22) Filed: Jul. 11, 2023

Related U.S. Application Data
(60) Provisional application No. 63/400,670, filed on Aug. 24, 2022.

(51) Int. Cl. G06F 1/16; G02B 27/00

(52) U.S. Cl. CPC G06F 1/163; G02B 27/0006

(57) ABSTRACT

A head-mounted device may include a main housing portion and displays in the main housing portion that provide images to eye boxes. A light seal may be coupled to the main housing portion and may at least partially surround the eye boxes. The head-mounted device may include sweat mitigation structures such as moisture-guiding channels in the light seal to guide sweat and other moisture away from the eye boxes. The moisture-guiding channels may be formed from grooves or moisture-wicking fabric. Control circuitry may adjust a fan based on humidity, temperature, or fog detected by a sensor. The light seal may include a directional pattern of grooves through which moisture is guided away from the eye boxes. A moisture barrier layer may be interposed between an inner foam layer and an outer light-blocking fabric to prevent sweat from penetrating into the foam.

This application claims the benefit of provisional patent application No. 63/400,670, filed Aug. 24, 2022, which is hereby incorporated by reference herein in its entirety.

### FIELD

This relates generally to electronic devices, and, more particularly, to wearable electronic devices such as head-mounted devices.

### BACKGROUND

Electronic devices such as head-mounted devices are configured to be worn on a head of a user. A head-mounted device may have left and right optical systems for presenting images to a user's left and right eyes. The optical systems may be mounted in a head-mounted housing. Conventional head-mounted devices can be uncomfortable to wear and may cause a user to sweat. If care is not taken, sweat can drip into a user's eyes or be absorbed into the head-mounted device, leading to odor and bacteria buildup.

### SUMMARY

Electronic devices such as head-mounted electronic devices may include a main housing portion. Displays and lenses may be mounted in the main housing portion. The displays may be configured to present images that are viewable from eye boxes.

A light seal may be coupled to the main housing portion and may extend at least partially around the eye boxes. The light seal may be configured to prevent outside light from leaking into the viewing area where the eye boxes are located. The light seal may include an inner foam layer and an outer light-blocking fabric.

The head-mounted device may include sweat mitigation structures such as moisture-guiding channels in the light seal to guide sweat and other moisture away from the eye box. The moisture-guiding channels may be formed from grooves or moisture-wicking fabric. Control circuitry may adjust a fan based on humidity, temperature, or fog detected by a sensor. The light seal may include a directional pattern of grooves through which moisture is guided away from the eye box. Venting holes may be formed in the light seal to allow for air exchange. The light seal may have one or more regions of increased friction to prevent slippage in the presence of sweat. A removable cooling structure may be coupled to the light seal. A moisture barrier layer may be interposed between an inner foam layer and an outer light-blocking fabric to prevent sweat from penetrating into the foam.

### BRIEF DESCRIPTION OF THE DRAWINGS

FIG. 1 is a top view of an illustrative head-mounted device in accordance with an embodiment.

FIG. 2 is a rear view of an illustrative head-mounted device in accordance with an embodiment.

FIG. 3 is a schematic diagram of an illustrative head-mounted device in accordance with an embodiment.

FIG. 4 is a top view of an illustrative head-mounted device with sweat mitigation structures in accordance with an embodiment.

FIG. 5 is a rear view of an illustrative head-mounted device having a light seal with sweat mitigation structures in accordance with an embodiment.

FIG. 6 is a side view of an illustrative light seal having sweat mitigation structures such as moisture-guiding channels formed from moisture-wicking fabric in accordance with an embodiment.

FIG. 7 is a perspective view of an illustrative light seal having sweat mitigation structures such as moisture-guiding channels formed from grooves in accordance with an embodiment.

FIG. 8 is a perspective view of an illustrative head-mounted device having sweat mitigation structures such as one or more sensors, one or more fans, and one or more moisture-guiding channels in accordance with an embodiment.

FIG. 9 is a side view of an illustrative head-mounted device having sweat mitigation structures such as one or more moisture-guiding channels configured to guide moisture away from a user's eyes and ears and towards a head band in accordance with an embodiment.

FIG. 10 is a rear view of an illustrative head-mounted device having a light seal with a directional pattern of grooves through which moisture is guided away from a user's eyes in accordance with an embodiment.

FIG. 11 is a rear view of an illustrative head-mounted device having a light seal with one or more venting holes and one or more increased-friction areas to avoid slippage on the face in accordance with an embodiment.

FIG. 12 is a rear view of an illustrative head-mounted device having a light seal with a removable cooling structure in accordance with an embodiment.

FIG. 13 is a side view of an illustrative light seal having a moisture barrier layer in accordance with an embodiment.

### DETAILED DESCRIPTION

An electronic device such as a head-mounted device may have a front face that faces away from a user's head and may have an opposing rear face that faces the user's head. Optical modules on the rear face may be used to provide images to a user's eyes. A light seal may be formed around the periphery of the head-mounted housing to help block outside light from leaking into the viewing area of the head-mounted device. The light seal may include one or more foam layers covered by a light-blocking fabric or other light-blocking layer. The light seal may include sweat mitigation structures to help prevent a user's sweat from dripping into the user's eyes or ears, penetrating into the foam of the light seal, or otherwise seeping into unwanted areas. The sweat mitigation structures may include one or more moisture-guiding channels on the light seal. Moisture-guiding channels may be formed from moisture-wicking fabric and/or grooves that help guide sweat or other moisture away from the user's eyes and ears and away from electronic components. The moisture may be guided to high-surface-area regions to be evaporated naturally or with the help of a fan in the head-mounted device. In some arrangements a removable cooling structure may be coupled to the light seal. Increased-friction regions on the light seal may be used to prevent slippage in the presence of perspiration, while one or more moisture barrier layers may help block sweat from reaching the foam inside of the light seal.

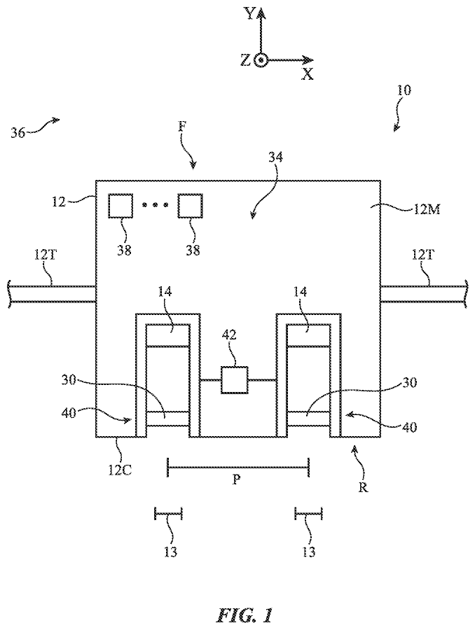

A top view of an illustrative head-mounted device that may include sweat mitigation structures is shown in FIG. 1. As shown in FIG. 1, head-mounted devices such as electronic device 10 may have head-mounted support structures such as housing 12. Housing 12 may include portions (e.g., support structures 12T) to allow device 10 to be worn on a user's head. Support structures 12T (sometimes referred to as temple housing structures, temple housing portions, a head strap, a head band, etc.) may be formed from fabric, polymer, metal, and/or other material. Support structures 12T may have one or more rigid portions that house electronic components (e.g., near the user's ears or temples) and one or more flexible portions that form a strap or head band to help support device 10 on a user's head. Some or all of temple housing portions 12T may overlap a user's temples when device 10 is worn on the user's head. A main support structure (e.g., main housing portion 12M) of housing 12 may support electronic components such as displays 14. Main housing portion 12M may include housing structures formed from metal, polymer, glass, ceramic, and/or other material. For example, housing portion 12M may have housing walls on front face F and housing walls on adjacent top, bottom, left, and right side faces that are formed from rigid polymer or other rigid support structures and these rigid walls may optionally be covered with electrical components, fabric, leather, or other soft materials, etc. The walls of housing portion 12M may enclose internal components 38 in interior region 34 of device 10 and may separate interior region 34 from the environment surrounding device 10 (exterior region 36). Internal components 38 may include integrated circuits, actuators, batteries, sensors, and/or other circuits and structures for device 10. Housing 12 may be configured to be worn on a head of a user and may form glasses, a hat, a helmet, goggles, and/or other head-mounted device. Configurations in which housing 12 forms goggles may sometimes be described herein as an example.

Front face F of housing 12 may face outwardly away from a user's head and face. Opposing rear face R of housing 12 may face the user. Portions of housing 12 (e.g., portions of main housing 12M) on rear face R may form a cover such as curtain 12C. In an illustrative configuration, curtain 12C includes a fabric layer that separates interior region 34 from the exterior region to the rear of device 10. Other structures may be used in forming curtain 12C, if desired. The presence of curtain 12C on rear face R may help hide internal housing structures, internal components 38, and other structures in interior region 34 from view by a user.

Device 10 may have left and right optical modules 40. Each optical module may include a respective display 14, lens 30, and support structure 32. Support structures 32, which may sometimes be referred to as lens barrels or optical module support structures, may include hollow cylindrical structures with open ends or other supporting structures to house displays 14 and lenses 30. Support structures 32 may, for example, include a left lens barrel that supports a left display 14 and left lens 30 and a right lens barrel that supports a right display 14 and right lens 30. Displays 14 may include arrays of pixels or other display devices to produce images. Displays 14 may, for example, include organic light-emitting diode pixels formed on substrates with thin-film circuitry and/or formed on semiconductor substrates, pixels formed from crystalline semiconductor dies, liquid crystal display pixels, scanning display devices, and/or other display devices for producing images. Lenses 30 may include one or more lens elements for providing image light from displays 14 to respective eyes boxes 13. Lenses may be implemented using refractive glass lens elements, using mirror lens structures (catadioptric lenses), using holographic lenses, and/or other lens systems. When a user's eyes are located in eye boxes 13, displays (display panels) 14 operate together to form a display for device 10 (e.g., the images provided by respective left and right optical modules 40 may be viewed by the user's eyes in eye boxes 13 so that a stereoscopic image is created for the user). The left image from the left optical module fuses with the right image from a right optical module while the display is viewed by the user.

Not all users have the same interpupillary distance P. To provide device 10 with the ability to adjust the interpupillary spacing between modules 40 along lateral dimension X and thereby adjust the spacing P between eye boxes 13 to accommodate different user interpupillary distances, device 10 may be provided with one or more actuators 42. Actuators 42 can be manually controlled and/or computer-controlled actuators (e.g., computer-controlled motors) for moving support structures 32 relative to each other.

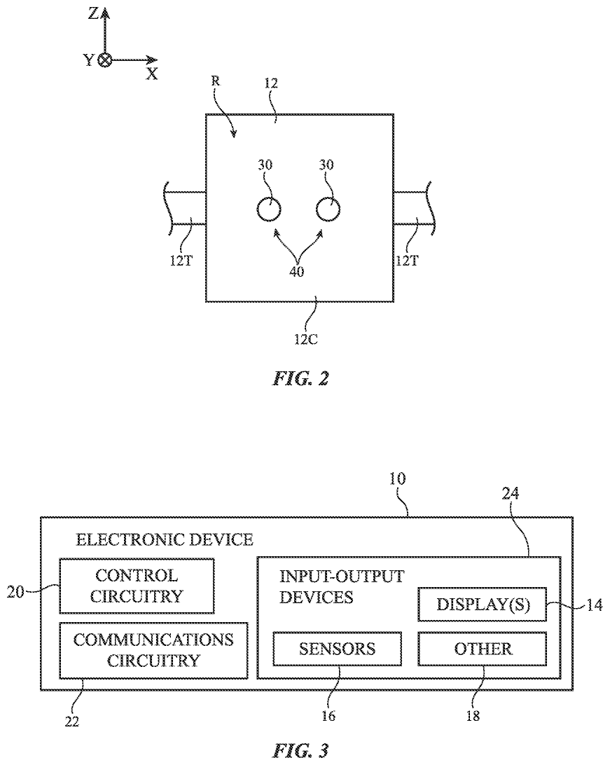

As shown in FIG. 2, curtain 12C may cover rear face F while leaving lenses 30 of optical modules 40 uncovered (e.g., curtain 12C may have openings that are aligned with and receive modules 40). As modules 40 are moved relative to each other along dimension X to accommodate different interpupillary distances for different users, modules 40 move relative to fixed housing structures such as the walls of main portion 12M and move relative to each other. To prevent undesired wrinkling and buckling of curtain 12C as optical modules 40 are moved relative to rigid portions of housing 12M and relative to each other, a fabric layer or other cover layer in curtain 12C may be configured to slide, stretch, open/close, and/or otherwise adjust to accommodate optical module movement.

A schematic diagram of an illustrative electronic device such as a head-mounted device or other wearable device is shown in FIG. 3. Device 10 of FIG. 3 may be operated as a stand-alone device and/or the resources of device 10 may be used to communicate with external electronic equipment. As an example, communications circuitry in device 10 may be used to transmit user input information, sensor information, and/or other information to external electronic devices (e.g., wirelessly or via wired connections). Each of these external devices may include components of the type shown by device 10 of FIG. 3.

As shown in FIG. 3, a head-mounted device such as device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use display(s) 14 and other output devices in providing a user with visual output and other output.

To support communications between device 10 and external equipment, control circuitry 20 may communicate using communications circuitry 22. Circuitry 22 may include antennas, radio-frequency transceiver circuitry, and other wireless communications circuitry and/or wired communications circuitry. Circuitry 22, which may sometimes be referred to as control circuitry and/or control and communications circuitry, may support bidirectional wireless communications between device 10 and external equipment (e.g., a companion device such as a computer, cellular telephone, or other electronic device, an accessory such as a point device, computer stylus, or other input device, speakers or other output devices, etc.) over a wireless link. For example, circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link. Wireless communications may, for example, be supported over a Bluetooth® link, a WiFi® link, a wireless link operating at a frequency between 10 GHz and 400 GHz, a 60 GHz link, or other millimeter wave link, a cellular telephone link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display(s) 14. Display(s) 14 may include one or more display devices such as organic light-emitting diode display panels (panels with organic light-emitting diode pixels formed on polymer substrates or silicon substrates that contain pixel control circuitry), liquid crystal display panels, microelectromechanical systems displays (e.g., two-dimensional mirror arrays or scanning mirror display devices), display panels having pixel arrays formed from crystalline semiconductor light-emitting diode dies (sometimes referred to as microLEDs), and/or other display devices.

Sensors 16 in input-output devices 24 may include force sensors (e.g., strain gauges, capacitive force sensors, resistive force sensors, etc.), audio sensors such as microphones, touch and/or proximity sensors such as capacitive sensors such as a touch sensor that forms a button, trackpad, or other input device), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, iris scanning sensors, retinal scanning sensors, and other biometric sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors such as blood oxygen sensors, heart rate sensors, blood flow sensors, and/or other health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, electromyography sensors to sense muscle activation, facial sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, actuators for moving movable housing structures, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

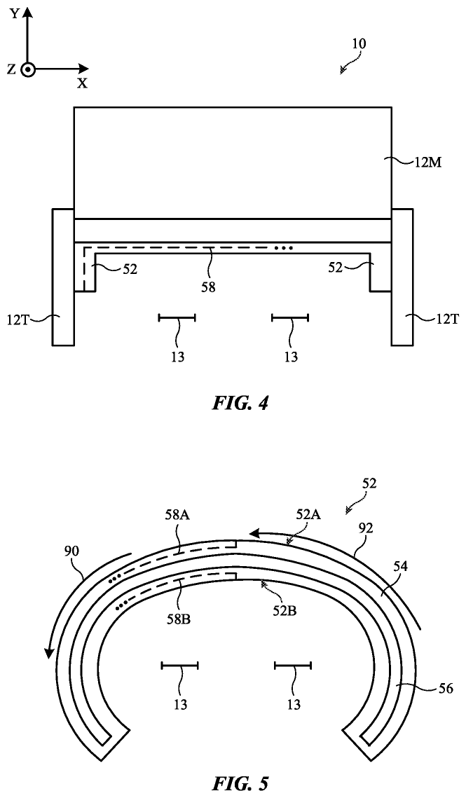

FIG. 4 is a top view of device 10 showing how a light seal may be used to help prevent outside light from leaking into the viewing area of head-mounted device 10. As shown in FIG. 4, device 10 may include main housing portion 12M which is configured to be mounted on a user's head using temple housing portions 12T. If desired, one or more electronic components may be mounted in temple housing portions 12T such as wireless charging circuitry, input-output devices (buttons, touch sensors, rotating knobs, speakers, etc.), sensors, etc. In other arrangements, temple housing portions 12T may be free of electronic components. Temple housing portions 12T may be formed using rigid support structures (e.g., to support electronic components) and/or flexible materials (e.g., to form a strap or head band).

To help block outside light (e.g., ambient light in the user's environment that is not emitted by displays 14 of device 10) from entering the viewing area of head-mounted device 10 where eye boxes 13 are located, a light seal such as light seal 52 may be formed between main housing portion 12M and the user's face. For example, light seal 52 may extend between main housing portion 12M and temple housing portions 12T to help prevent light from entering any gaps between device 10 and the user's face.

As shown in FIG. 4, light seal 52 may include sweat mitigation structures such as one or more moisture-guiding channels 58. Moisture-guiding channels 58 may be formed from grooves and/or moisture-wicking fabric that helps guide sweat and other moisture away from the user's eyes and ears and away from electronic components. The moisture may be guided to reservoirs and/or high-surface-area regions where the moisture can be evaporated naturally or by a fan in device 10. If sweat forms on the user's face during use of device 10, the sweat may drip into channel 58 where it is guided away from unwanted areas such as the eyes.

A rear view of light seal 52 is shown in FIG. 5. As shown in FIG. 5, light seal 52 may be a horseshoe-shaped opaque light seal, may be a ring-shaped opaque light seal, or may have other suitable shapes (e.g., an oval shape, a rectangular shape, a C-shape, a U-shape, an arc shape, etc.). If desired, light seal 52 may be configured to be removable (e.g., so that light seal 52 may be replaced when worn) and/or may have parts such as a user-facing portion that is removable from the rest of light seal 52. Foam or other soft materials such as fabric may be used in forming light seal 52. For example, light seal 52 may include foam such as inner foam layer 56 inside of a light-blocking cover such as light-blocking cover 54. If desired, other support structures such as a flexible plastic frame may be incorporated into light seal 52 (e.g., inside of light-blocking cover 54).

Light seal 52 may curve around the optical modules of device 10 (e.g., around and over the top of optical modules 30 of FIG. 2) and may extend across the user's forehead and at least partially onto the temples. Light-blocking cover 54 may form a canopy across the user's forehead (e.g., above optical modules 30) and may extend at least partially onto the temples (e.g., to the left and right of optical modules 30). This helps block light from leaking between the user's forehead and device 10 as well as between the user's temples and device 10.

Light-blocking cover 54 may be formed from one or more layers of fabric, polymer, elastomer, or other suitable materials. In one illustrative arrangement, light-blocking cover includes a stretchable fabric outer layer and a light-blocking fabric inner layer or a light-blocking inner layer formed from other materials. Light-blocking cover 54 may be configured to stretch and/or otherwise expand and retract to allow some movement of main housing portion 12M relative to temple housing portions 12T. This allows device 10 to accommodate different face shapes.

As shown in FIG. 5, sweat mitigation structures may include one or more moisture-guiding channels such as outer moisture-guiding channel 58A and inner moisture-guiding channel 58B. Outer moisture-guiding channel 58A may be formed on exterior surface 52A of light seal 52 (e.g., an outer surface of light-blocking cover 54 facing away from eye boxes 13). Inner moisture-guiding channel 58B may be formed on interior surface 52B of light seal 52 (e.g., an inner surface of light-blocking cover 54 facing towards eye boxes 13). There may be any suitable number of moisture-guiding channels 58 (e.g., one, two, five, ten, more than ten, more than twenty, less than twenty, etc.) arranged in any suitable pattern (e.g., straight, curved, zig-zag, symmetric patterns, asymmetric patterns, and/or any other suitable pattern). Sweat mitigation structures such as channels 58 may be formed on light seal 52 and/or may be formed on other portions of device 10 such as temple housing portions 12T and/or any other structure that is adjacent to the user's face.

In some arrangements, moisture-guiding channels 58 may guide sweat in direction 90 to a location outside of light seal 52 (e.g., to a head band formed from temple housing portions 12T). In some arrangements, moisture-guiding channels 58 may wick sweat in direction 92 against the flow of gravity (e.g., to an uppermost surface of light seal 52 where the sweat can evaporate).

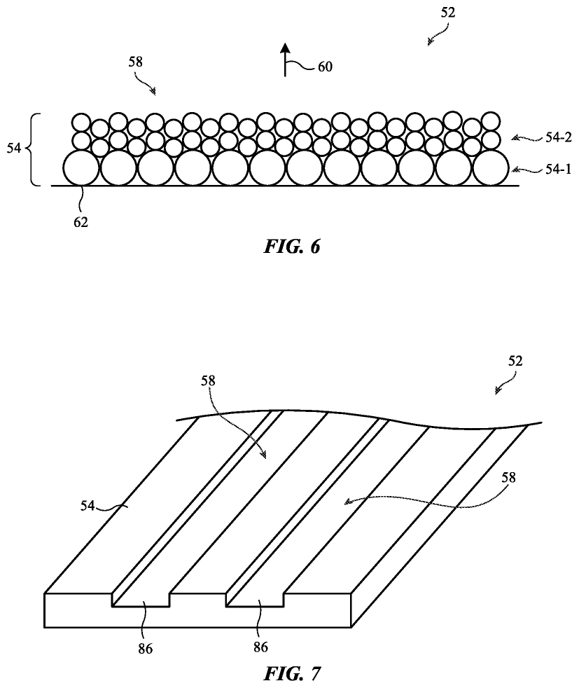

FIG. 6 is a cross-sectional side view of a portion of light seal 52 showing an illustrative arrangement in which moisture-guiding channel 58 is formed from a moisture-wicking fabric that promotes the wicking of moisture away from the user's face. As shown in FIG. 6, light seal 52 may include fabric 54. Fabric 54 may include portions such as inner portion 54-1 (e.g., a layer facing towards the user's face 62) and outer portion 54-2 (e.g., a layer facing away from the user's face). Inner portion 54-1 may have strands of material with a larger linear density per filament (e.g., a larger denier per filament value) than outer portion 54-2. The smaller denier per filament value of layer 54-2 ensures that layer 54-2 has more surface area than layer 54-1 and therefore helps layer 54-2 create a strong capillary action that draws moisture outwardly through fabric 54 in direction 60. The smaller denier per filament value of layer 54-2 also promotes evaporation of moisture into the surrounding environment. The larger denier per filament of layer 54-1 allows rapid moisture movement from face 62 through fabric 54 in direction 60 and helps reduce moisture retention in fabric 54 near face 62 to enhance comfort. Portions of fabric 54 that contact face 62 may be modified to enhance comfort (e.g., strands of material in fabric layer 54-1 or other portions of fabric 54 in contact with face 62 may be bulked, air twisted, or brushed to enhance comfort). If desired, the entirety of fabric 54 may be formed from moisture-wicking fabric of the type shown in FIG. 6, or only certain regions of fabric 54 may be formed from moisture-wicking fabric. For example, fabric 54 may include moisture-wicking fabric in channels 58 to wick sweat and other moisture to a different location (e.g., outside of light seal 52, on a head band formed from temple housing portions 12T, to an uppermost surface of light seal 52, and/or other suitable locations), while other regions of fabric 54 where channels 58 are not present may have a different fabric construction.

Any suitable materials may be used in forming the strands of fabric 54. For example, the strands of material in fabric 54 may be formed from materials such as polyester, nylon (e.g., polyamide, nylon 6, nylon 66, etc.), or polypropylene. These materials may exhibit low moisture regain (low moisture absorbed into the bulk material of the strand), thereby preventing fabric 54 from becoming saturated with moisture when a user's face becomes moist and helping to ensure that moisture is free to move through open pores in fabric 54 by capillary action.

Fabric 54 may include stands with any suitable filament count ranging from single filament strands (monofilaments) to strands with fifty or more filaments. The strands (yarns) may have any suitable denier per strand value and any suitable denier per filament value.

For example, weft strands for fabric 54 may be formed from 50 denier blended yarn having two intertwined strands each of which contains 53 filaments. If desired, the weft strands may have denier values of more than 25 denier per strand, more than 50 denier per strand, less than 100 denier per strand, less than 75 denier per strand, or other suitable values. Weft strands may have more than 20 filaments per strand, more than 40 filaments per strand, more than 100 filaments per strand, fewer than 150 filaments per strand, fewer than 120 filaments per strand, fewer than 70 filaments per strand, etc.

Fabric 54 may have strands (e.g., warp strands) with that each have a denier value of 50-150 denier, more than 40 denier, or less than 200 denier. The strands for moisture management layers such as layers 54-1 and 54-2 of FIG. 6 may each have 10-36 filaments, 2-150 filaments, more than 10 filaments, more than 20 filaments, more than 30 filaments, 10-13 filaments, 10-36 filaments, fewer than 36 filaments, 106 filaments, 30-120 filaments, fewer than 130 filaments, or other suitable number of filaments.

Layer 54-1 may have a denier per filament of 3 and layer 54-2 may have a denier per filament of 1 (i.e., the ratio of the denier per filament values of layer 54-1 to 54-2 may be 3:1) or these layers may have other denier per filament values. For example, the denier per filament of layer 54-2 may be 1-6, may be more than 1, more than 2, more than 3, more than 5 less than 10, etc. The denier per filament of layer 54-2 may be 0.5-4, may be more than 0.5, more than 1, more than 2, more than 3, more than 5 less than 6, etc. The ratio of the denier per filament value of layer 54-1 to that of layer 54-2 may be 3, 2-4, more than 1.2, more than 1.5, more than 2, more than 3, more than 4, more than 8, less than 10, less than 5, or other suitable value.

FIG. 7 is a perspective view of light seal 52 showing another illustrative arrangement in which moisture-guiding channel 58 is formed from grooves that guide moisture away from the user's face. As shown in FIG. 7, moisture-guiding channels 58 may be formed from grooves 86 (sometimes referred to as trenches, recesses, cavities, treads, holes, gaps, openings, etc.) that extend partially or entirely through fabric 54. Grooves 86 may be formed by removing material from fabric 54 (e.g., using laser ablation or other cutting techniques), may be formed by molding, may be formed by fusing strands in fabric 54, and/or may be formed by the construction of fabric 54 itself (e.g., by creating gaps between the strands that form fabric 54, by weaving, knitting, braiding, and/or otherwise interlacing strands to form grooves 86, by stitching multiple layers together in stacks around spaces that form grooves 86, etc.).

The arrangement of FIG. 7 in which grooves 86 are straight and parallel to one another is merely illustrative. If desired, grooves 86 may follow curved paths, meandering paths, zig-zag paths, segmented (non-continuous) paths, and/or any other suitable path. Different grooves 86 may follow different directions, may be symmetric or asymmetric with one another, and/or may have any other suitable pattern.

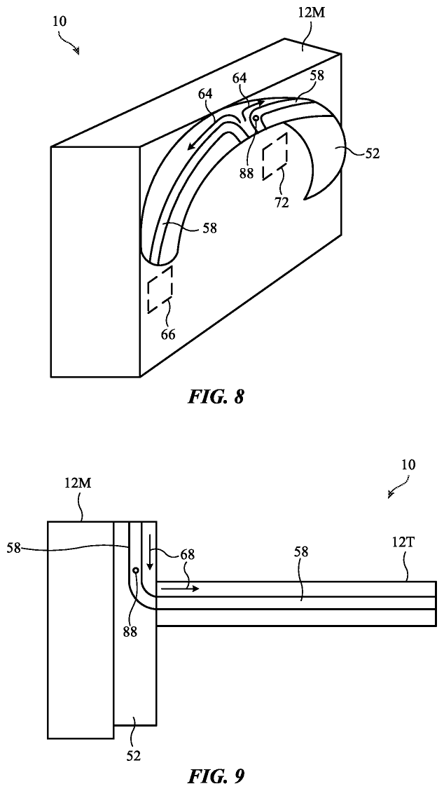

FIG. 8 is a perspective view of device 10 showing how moisture-guiding channels 58 may guide moisture away from the face. During extended use, a user may perspire and create sweat 88. Channel 58 may be located adjacent to the user's face so that sweat 88 is caught by channel 58 and guided away from the user's eyes in directions 64. Channel 58 may be formed from a moisture-wicking fabric region of the type shown in FIG. 6 or may be formed from grooves 86 of the type shown in FIG. 7.

If desired, one or more fans such as fan 66 in device 10 may be used to assist with evaporating sweat 88. Control circuitry 20 may turn fan 66 on whenever device 10 is turned on, or control circuitry 20 may turn fan 66 on at certain times (e.g., when device 10 is turned on for an extended period of time, when device 10 reaches a certain operating temperature, etc.). In one illustrative arrangement, device 10 includes a sensor such as sensor 72 for assessing when fan 66 should be turned on. Sensor 72 may be a temperature sensor for detecting temperature near the user's face, a humidity sensor for detecting a humidity level near the user's face, an optical sensor for detecting fog near the user's face, and/or other sensor. Control circuitry 20 may monitor sensor data (e.g., temperature information, humidity information, fog information, etc.) from sensor 72 to determine when sweat mitigation measures should be taken. For example, if sensor 72 detects that the temperature, humidity, or fog within the area surrounded by light seal 52 in front of the user's face exceeds a certain threshold, control circuitry 20 may turn on fan 66 or adjust the speed of fan 66 accordingly. Fan 66 may be used to help evaporate sweat 88 and/or may be used to help cool down the user's face.

In some arrangements, sweat 88 may be guided to a reservoir in light seal 52 or a reservoir located elsewhere in device 10. In other arrangements, sweat 88 may be guided to a moisture-absorbing structure such as a towel-like fabric that can be removed for cleaning after use. Arrangements in which sweat 88 is guided against the flow of gravity to a high-surface-area region (e.g., on an uppermost surface of light seal 52) may also be used.

In some arrangements, sweat 88 may be guided to a high-surface-area region outside of light seal 52 so that the moisture can evaporate more quickly (e.g., by evaporating naturally or with the help of a fan in device 10). FIG. 9 is a side view of device 10 showing an illustrative arrangement in which moisture-guiding channel 58 guides moisture to a high-surface-area region such as a head strap. As shown in FIG. 9, moisture-guiding channel 58 (e.g., a moisture-wicking fabric region of the type shown in FIG. 6 or one or more grooves 86 of the type shown in FIG. 7) may guide moisture 88 away from the upper forehead region of seal 52 and towards temple housing portions 12T. Temple housing portion 12T may include a strap or band that wraps partially or completely around the back of the user's head (and over the top of the user's head, if desired). Due to the large surface area of the head strap and its location away from the user's face, the head strap may be a good location for receiving excess sweat from the user's face. Moisture-guiding channel 58 may guide sweat 88 to the strap formed from temple housing portion 12T where the sweat 88 can be evaporated without interfering with the user's eyes and ears and without interfering with electronics in device 10.

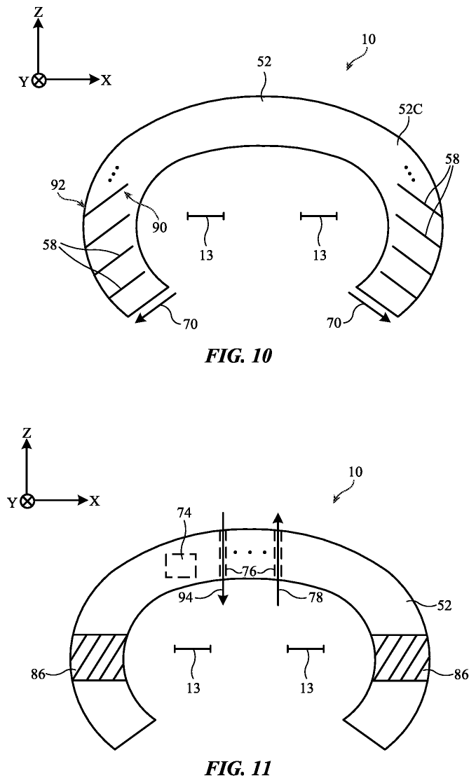

FIG. 10 is a rear view of device 10 showing how moisture-guiding channels 58 may form a directional pattern in light seal 52. As shown in FIG. 10, moisture-guiding channels 58 may include a pattern of angled grooves (sometimes referred to as directional or unidirectional grooves) that are configured to guide moisture in an outward direction (e.g., direction 70) away from the user's eyes. Channels 58 may be formed in a rear surface of light seal 52 (e.g., user-facing surface 58C facing the user's face when device 10 is mounted on a user's head). If desired, channels 58 may be angled such that the inner end 90 of each channel 58 (e.g., the end closer to eye boxes 13) is higher up on the user's face than the opposing outer end 92, so that gravity can help guide moisture outward away from eye boxes 13. Due to the angle of grooves 58, sweat and other moisture may be guided within grooves 58 away from eye boxes 13. Channels 58 on user-facing surface 58C of light-seal 52 may be used in addition to or instead of moisture-guiding channels 58 in other locations of light seal 52 (e.g., on exterior surface 52A of light seal 52 and/or interior surface 52B of light seal 52).

Directional channels 58 may be formed by removing material from fabric 54 (e.g., using laser ablation or other cutting techniques), may be formed by molding, may be formed by fusing strands in fabric 54, and/or may be formed by the construction of fabric 54 itself (e.g., by creating gaps between the strands that form fabric 54, by weaving, knitting, braiding, and/or otherwise interlacing strands to form channels 58, by stitching multiple layers together in stacks around spaces that form channels 558, etc.). In some arrangements, fabric 54 may be a cushion textile (e.g., a spacer fabric having inner and outer warp knit layers joined by a spacer layer) and the directional pattern of channels 58 may be formed from grooves in the cushion textile.

FIG. 11 is a rear view of device 10 showing an illustrative arrangement in which light seal 52 includes one or more venting holes. As shown in FIG. 11, light seal 52 may include one or more holes such as holes 76. Holes 76 may allow air to pass through light seal 52 (e.g., without allowing light through) so that the user's face remains cool. For example, hot air generated near eye boxes 13 may be allowed to escape through openings 76 in direction 78 and cool outside air may be allowed into the region near eye boxes 13 through openings 76 in direction 94. Holes 76 may be perforations, slits, or other openings for allowing air exchange. Holes 76 may be located above eye boxes 13 and/or may be located elsewhere in light seal 52. If desired, one of openings 76 may be a slit that is big enough to allow a user to reach through light seal 52 and wipe sweat off of the user's brow. A fan such as fan 74 may be configured to provide airflow to help the exchange of air and provide cooling effects. Fan 74 may be located in light seal 52 or may be located in main housing portion 12M of device 10. Holes 76 in light-seal 52 may be used in addition to or instead of moisture-guiding channels 58 in other locations of light seal 52 (e.g., on exterior surface 52A of light seal 52, interior surface 52B of light seal 52, and/or user-facing surface 52C of light seal 52).

If desired, light seal 52 may include areas of increased friction to help avoid slippage of device 10 relative to the user's face in the presence of perspiration. As shown in FIG. 11, for example, light seal 52 may include grip regions 86. Grip regions 86 may be formed using higher friction materials in fabric 54 (e.g., silicone strands, polyurethane strands, etc.), may be formed using higher friction fabric constructions (e.g., knit fabric regions), may be formed from patches of material on the surface of fabric 54 (e.g., silicone patches), may be formed from fused portions of fabric 54, and/or may be formed using other structures. Grip regions 86 may be formed throughout the surface area of light seal 52 contacting the user's face or may only be formed in certain regions such as left and right temple regions, brow regions, etc.

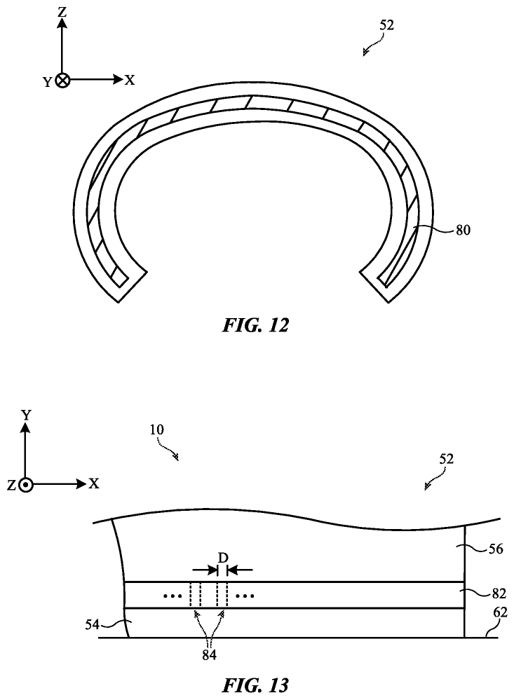

FIG. 12 is a rear view of device 10 showing an illustrative arrangement in which a cooling structure is attached to light seal 52. As shown in FIG. 12, a cooling structure such as removable cooling structure 80 may be removably attached to light seal 52. Cooling structure 80 may be inserted into light seal 52 (e.g., to fit inside of fabric 54) or may be attached to the outside of light seal 52 (e.g., the rear surface of light seal 52 that rests against the user's face). Cooling structure 80 may be a gel, fluid, or other material in a casing that can be chilled or frozen and then attached to light seal 52. In other arrangements, cooling structure 80 may be a phase-change material that cools when contacted by warm skin. Arrangements in which fabric 54 of light seal 52 is formed from phase-change fabric and/or antimicrobial fabric may also be used, if desired. Removable cooling structure 80 may be used in addition to or instead of moisture-guiding channels 58 in other locations of light seal 52 (e.g., on exterior surface 52A of light seal 52, interior surface 52B of light seal 52, and/or user-facing surface 52C of light seal 52).

In addition to helping guide sweat away from the user's eyes using channels 58, it may be desirable to prevent sweat from reaching the foam inside of light seal 52. FIG. 13 is a cross-sectional side view of light seal 52 showing how a moisture barrier layer may be used to block sweat from reaching foam inside of light seal 52. As shown in FIG. 13, light seal 52 may include outer fabric layer 54 surrounding foam 54. A barrier layer such as moisture barrier layer 82 may be interposed between foam 56 and fabric 54. Moisture barrier layer 82 may be a layer of silicone, polymer, moisture-wicking fabric, or other suitable material. Moisture barrier layer 82 may be a solid layer or may have one or more openings to allow the passage of air. For example, moisture barrier layer 82 may include one or more perforations 84 to allow breathability. The diameter D of openings 84 may be sufficiently small so that sweat does not pass through to foam 56 (e.g., due to surface tension).

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

Physical environment: A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

Computer-generated reality: in contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands). A person may sense and/or interact with a CGR object using any one of their senses, including sight, sound, touch, taste, and smell. For example, a person may sense and/or interact with audio objects that create 3D or spatial audio environment that provides the perception of point audio sources in 3D space. In another example, audio objects may enable audio transparency, which selectively incorporates ambient sounds from the physical environment with or without computer-generated audio. In some CGR environments, a person may sense and/or interact only with audio objects. Examples of CGR include virtual reality and mixed reality.

Virtual reality: A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

Mixed reality: In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end. In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationery with respect to the physical ground. Examples of mixed realities include augmented reality and augmented virtuality. Augmented reality: an augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment. An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof. Augmented virtuality: an augmented virtuality (AV) environment refers to a simulated environment in which a virtual or computer generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

Hardware: there are many different types of electronic systems that enable a person to sense and/or interact with various CGR environments. Examples include head mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head mounted system may have one or more speaker(s) and an integrated opaque display. Alternatively, a head mounted system may be configured to accept an external opaque display (e.g., a smartphone). The head mounted system may incorporate one or more imaging sensors to capture images or video of the physical environment, and/or one or more microphones to capture audio of the physical environment. Rather than an opaque display, a head mounted system may have a transparent or translucent display. The transparent or translucent display may have a medium through which light representative of images is directed to a person's eyes. The display may utilize digital light projection, OLEDs, LEDs, μLEDs, liquid crystal on silicon, laser scanning light sources, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

The foregoing is merely illustrative and various modifications can be made to the described embodiments. The foregoing embodiments may be implemented individually or in any combination.

What is claimed is:

1. A head-mounted device, comprising:
a main housing portion;
a display in the main housing portion that is configured to provide an image viewable from an eye box; and
a light seal coupled to the main housing portion, wherein the light seal at least partially surrounds the eye box and has a moisture-guiding channel configured to guide moisture to a location outside of the light seal.

2. The head-mounted device defined in claim 1 further comprising a head band coupled to the main housing portion, wherein the moisture-guiding channel is configured to guide the moisture to the head band.

3. The head-mounted device defined in claim 1 wherein the moisture-guiding channel is located on an exterior surface of the light seal.

4. The head-mounted device defined in claim 1 wherein the moisture-guiding channel is located on an interior surface of the light seal.

5. The head-mounted device defined in claim 1 wherein the moisture-guiding channel comprises a groove in the light seal.

6. The head-mounted device defined in claim 1 wherein the moisture-guiding channel comprises a moisture-wicking fabric.

7. The head-mounted device defined in claim 6 wherein the moisture-wicking fabric comprises at least first and second fabric layers, wherein the first fabric layer has strands with a first denier per filament value and wherein the second fabric layer has strands with a second denier per filament value that is less than the first denier per filament value.

8. The head-mounted device defined in claim 1 wherein the light seal comprises foam surrounded by a light-blocking fabric and wherein the moisture-guiding channel is located in the light-blocking fabric.

9. The head-mounted device defined in claim 1 further comprising:
a sensor;
a fan; and
control circuitry configured to adjust the fan based on information from the sensor, wherein the information is selected from the group consisting of: temperature information, humidity information, and fog information.

10. The head-mounted device defined in claim 1 further comprising a removable cooling structure coupled to the light seal.

11. A head-mounted device, comprising:
a main housing portion;
a display in the main housing portion that is configured to provide an image viewable from an eye box; and
a light seal coupled to the main housing portion, wherein the light seal at least partially surrounds the eye box and has a directional pattern of grooves angled such that moisture is guided within the grooves away from the eye box.

12. The head-mounted device defined in claim 11 wherein the light seal comprises foam and a light-blocking fabric that covers the foam.

13. The head-mounted device defined in claim 12 wherein the directional pattern of grooves is located in the light-blocking fabric.

14. The head-mounted device defined in claim 13 wherein the light-blocking fabric comprises a spacer fabric.

15. A head-mounted device, comprising:
a main housing portion;
a display in the main housing portion that is configured to provide an image viewable from an eye box; and
a light seal coupled to the main housing portion and at least partially surrounding the eye box, wherein the light seal comprises:
foam;
a light-blocking fabric that covers the foam; and
a moisture barrier layer interposed between the foam and the light-blocking fabric that is configured to prevent moisture from penetrating into the foam.

16. The head-mounted device defined in claim 15 wherein the moisture barrier layer comprises silicone.

17. The head-mounted device defined in claim 15 wherein the moisture barrier layer comprises perforations for allowing air passage without allowing moisture passage.

18. The head-mounted device defined in claim 15 wherein the light seal has a moisture-guiding channel through which moisture is guided away from the eye box.

19. The head-mounted device defined in claim 15 wherein the light seal comprises a portion with increased friction relative to other portions of the light seal.

20. The head-mounted device defined in claim 19 wherein the portion with increased friction comprises a patch of material selected from the group consisting of: silicone, polyurethane, and fused fabric.
